(19) United States
(12) Patent Application Publication
(10) Pub. No.: US 2003/0230794 A1
(43) Pub. Date: Dec. 18, 2003

(54) Semiconductor fabrication method and apparatus, and semiconductor device

(75) Inventors: Yoshiaki Narita, Kawasaki (JP); Umeo Osio, Sagamihara (JP)

Correspondence Address: Patrick G. Burns, Esq., GREER, BURNS & CRAIN, LTD., 300 South Wacker Dr., Suite 2500, Chicago, IL, 60606, US

(73) Assignee: FUJITSU LIMITED

(21) Appl. No.: 10/417,407

(22) Filed: Apr. 16, 2003

(30) Foreign Application Priority Data
Apr. 18, 2002 (JP) 2002-116806

(51) Int. Cl. H01L 23/495

(52) U.S. Cl. 257/673

(57) ABSTRACT

A semiconductor fabrication method includes the steps of bonding each a plurality of bonding pads provided in a die and a circuit board using wire, coating an interface between the bonding pad and the wire with a buffer material, and sealing part of the die and the circuit board.

### BACKGROUND OF THE INVENTION

The present invention relates generally to semiconductor fabrication methods, and more particularly to a bonding method. The present invention is also relates to a bonded intermediate product and an end product, like LSIs.

An LSI is generally experiences a bonding step of mounting a die or chip onto a lead frame or package, and then a sealing or packaging step of sealing them using resin. The bonding step has used such a jointing material as gold and resin for mounting of the die. FIG. 8 shows a schematic sectional view of a conventional LSI package 1 after the sealing step. In the LSI package 1, as illustrated, an IC chip 12 mounted on a stage 10 is bonded to a lead frame 14 through gold balls 17 and wires 18, and then sealed by plastic 20. The gold ball 17 is formed at an end of the gold wire 18 and metal-jointed to a bonding pad 16 as a metal-coated electrode on the IC chip 12, so as to connect the IC chip 12 to the gold wire 18. The instant application sometimes refers to an interface between a bonding pad and a wire or an area including the interface as a bonding pad part, as enclosed by a broken line labeled by 16 shown in FIG. 8.

Recent trends of ecological protections have required LSIs to follow environmental conservation or afforestation. Use of unleaded solder has recently been proposed as one solution in mounting the package 1 onto a printed board. Lead is innocent in a metal state, but it has been pointed out that acid rain resulted from industrial waste etc. dissolves lead, possibly causing water pollution. Demands of unleaded solder have increased particularly in Europe. Although various types of unleaded solder have been proposed which include tin/silver alloy and tin/silver/cupper alloy, it becomes necessary to locate the package 1 under higher temperature conditions than the conventional in mounting the package 1 onto the printed board since the unleaded solder usually has a melting point (of, for example, about 260° C.) higher than that of the leaded solder (of, for example, about 225° C.).

The LSI package 1 is integrally formed with the plastic 20, the IC chip 12 and bonding pad parts 16. Thus, as the printed board becomes high temperature due to the unleaded soldering, the physical pressure applies to the bonding pad part 16 due to a difference in coefficient of thermal expansion between the plastic 20 and the IC chip 12, causing a disadvantageous disconnection on the bonding pad part 16. A description will be given of this problem with reference to FIGS. 8 and 9. Here, FIG. 9A is an enlarged sectional view of the boding pat part 16 shown in FIG. 8 at room temperature, and FIG. 9B is an enlarged sectional view of the bonding pad part 16 shown in FIG. 9A at high temperature. As shown in FIGS. 8 and 9, different coefficients of thermal expansion between the plastic 20 and the IC chip 12 generate thermal stresses F₁ and F₂. Then, a difference of thermal stresses F₂-F₁ applies as a distortion to an interface between the gold ball 17 and gold wire 18, as shown in an arrow in FIG. 9B, possibly causing the disconnection. In addition, the disconnection lowers a yield of manufacture of the printed boards.

It is conceivable as one solution not to fill the plastic 20 on and around the bonding pad part 16 in filling the plastic 20 in packaging. Such a sealing method would result in complex working and increased fabrication cost.

### BRIEF SUMMARY OF THE INVENTION

Accordingly, it is an exemplified object of the present invention to provide a semiconductor fabrication method and apparatus, which may manufacture a package having improved heat resistance, and a semiconductor device having the package.

In order to achieve the above object, a semiconductor fabrication method as one aspect of the present invention includes the steps of bonding each of a plurality of bonding pads provided in a die and a circuit board using a wire, coating an interface between the bonding pad and the wire with a buffer material, and sealing the die and part of the circuit board using resin. According to this semiconductor fabrication method, the buffer material coats the interface. The wire in the buffer material is deformable like a linkage, thereby buffering a distortion caused by different coefficients of thermal expansion between the resin and die.

The method may further include the step of using unleaded solder to mount, onto a printed board, a package that is formed by the sealing step and includes the resin, circuit board and die. The package of the present invention particularly exhibits the heat resistance under the high temperature environment using unleaded soldering.

The buffer material may be a jelly material, a viscosity material, etc., have a melting point lower than the temperature in the sealing step, and be implemented, for example, as silicon rubber. The coating step may apply the buffer material onto each interface, onto a row of the bonding pads or onto the approximately entire surface of the die.

A semiconductor device as another aspect of the invention includes a die having a plurality of bonding pads and bonded to a circuit board through the bonding pads and wires, and a buffer material for coating an interface between the bonding pad in the die and the wire. According to this semiconductor device, the buffer material coats the interface, and thus the wire in the buffer material becomes deformable like a linkage.

A semiconductor device as still another aspect of the present invention includes a package including a die that has a plurality of bonding pads and is bonded to a lead frame through the bonding pads and wires, and a buffer material for coating an interface between the bonding pad in the die and the wire, and a printed board mounted with the package through unleaded soldering. This semiconductor device uses the unleaded solder, contributing to environment protection, while the package does not cause a disconnection between the bonding pad and wire, exhibiting good electric property. Various electronic apparatuses, such as computers, cell phones, audio-visual apparatuses, printers, etc., which have the above semiconductor device, constitute another aspect of the present invention.

A semiconductor fabrication apparatus of another aspect of the present invention includes an application part for applying a buffer material to a die that has a plurality of bonding pads and is bonded to a circuit board through the bonding pads and wires, at an interface between the bonding pad and wire, and a moving part for moving the application part such that the application part may apply the buffer material to the interface corresponding to each of the plurality of bonding pads. This semiconductor fabrication apparatus may also manufacture the above semiconductor device. The application part may apply the buffer material to each interface locally or the approximately entire surface of the die.

Other objects and further features of the present invention will become readily apparent from the following description of the embodiments with reference to accompanying drawings.

### BRIEF DESCRIPTION OF THE DRAWINGS

FIG. 1 is a flowchart for explaining a semiconductor fabrication method as one embodiment of the present invention.

FIG. 2 is a schematic sectional view corresponding to each step shown in FIG. 1.

FIG. 3 is a schematic perspective view for explaining a method of applying a buffer material onto each bonding pad part.

FIG. 4 is a schematic sectional view showing one exemplary structure of a coating applicator for applying the buffer material.

FIG. 5 is a schematic sectional view and plane view for explaining a variation of the application method shown in FIG. 3.

FIG. 6 is a schematic sectional view for explaining an effect of a package of the instant embodiment.

FIG. 7 is a perspective overview of a laptop personal computer as one example of an electronic apparatus mounted with an inventive printed board.

FIG. 8 is a schematic sectional view of a conventional LSI package after a sealing step.

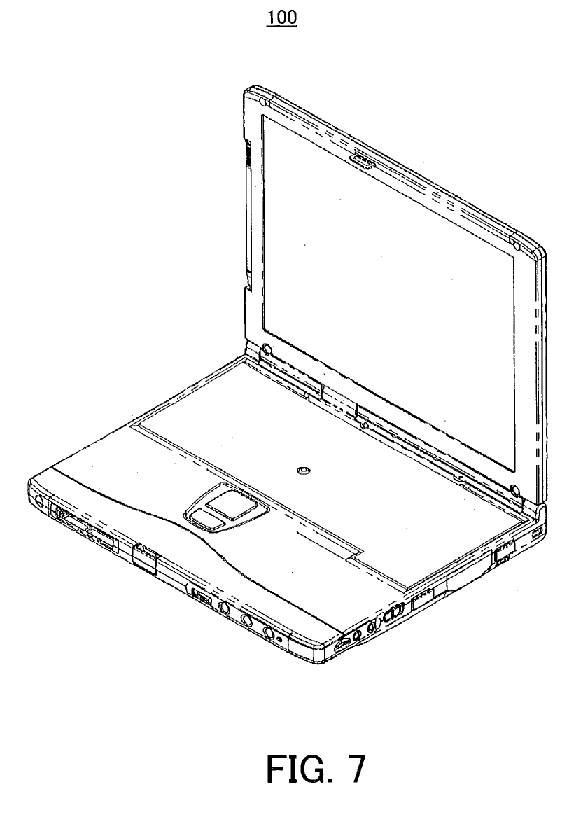

FIG. 9A is an enlarged sectional view of a bonding pad part shown in FIG. 8 at room temperature, and FIG. 9B is an enlarged sectional view of the bonding pad part shown in FIG. 9A at high temperature.

### DETAILED DESCRIPTION OF THE INVENTION

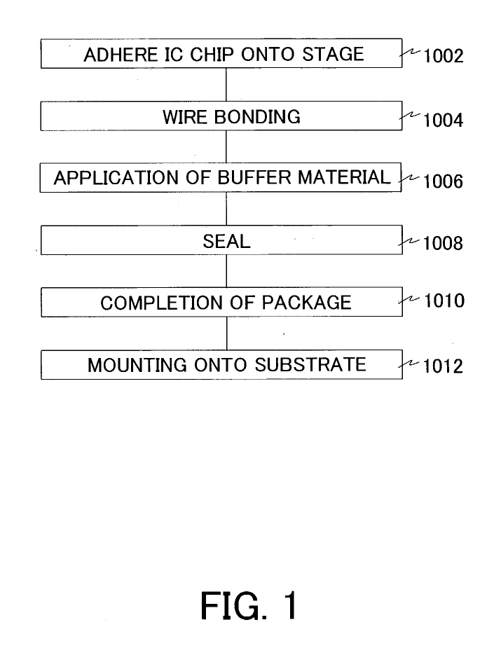

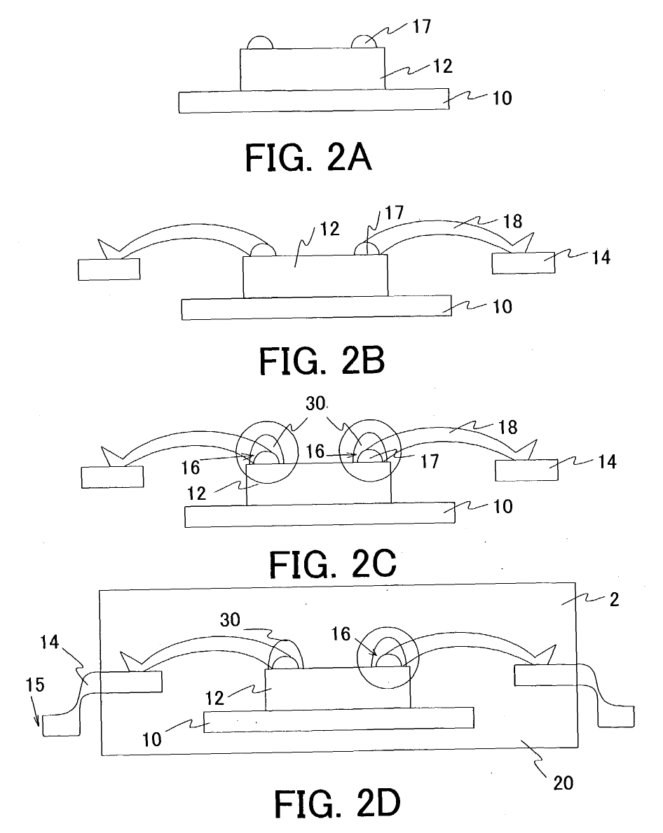

Referring now to accompanying drawings, a description will be given of a semiconductor fabrication method as one embodiment according to the present invention. Here, FIG. 1 is a flowchart for explaining a semiconductor fabrication method as one embodiment of the present invention. FIG. 2 is a schematic sectional view corresponding to each step in FIG. 1.

First, as shown in FIG. 2A, the IC chip 12 is adhered to the stage 10 (step 1002). Then, as shown in FIG. 2B, the IC chip 12 and the lead frame 14 are bonded using gold, aluminum and other wires 18 (step 2004).

As shown in FIG. 2C, the buffer material 30 is applied onto a bonding pad part (step 1006). The quantity of application of the buffer material 30 depends upon a size of the bonding pad part. The range and height of the applied buffer material 30 may be adjustable by adjusting temperature and viscosity. The buffer material 30 is made of a non-solid material, such as a jelly material and a viscosity material, has a melting point lower than the temperature in the sealing step, and may be made, for example, of silicon rubber. The buffer material 30 may be in a non-solid state at least in a mounting step (step 1012), which will be described later, and it may then turn to be in a solid state.

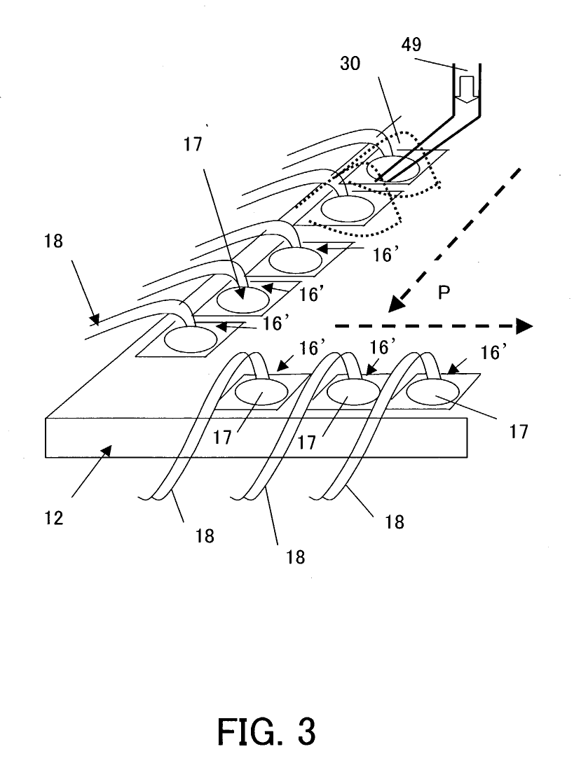

The coating applicator 40 for applying the buffer material 30 has a structure similar to that of a known dispenser, and includes, as shown in FIG. 4, a buffer-material supply 42, a plunger or cylinder 46 for charging and discharging the buffer material 30, a valve 44 provided between the buffer-material supply 42 and the cylinder 46 for controlling flow of the buffer material 30, and a cylinder block 48 that supports the plunger 46, accommodates the buffer material 30 and has a nozzle 49 at its top. For example, as the cylinder 46 goes up the valve 44 opens, thereby charging the flow-controlled buffer material 30 in the cylinder block 48 from the buffer-material supply 42. Then the valve 44 closes as the cylinder 47 goes down, thereby applying the buffer material 30 filled in the cylinder block 48 onto the bonding pad part 16 from the tip of the nozzle 49 in the arrow direction. Here, FIG. 4 is a schematic sectional view showing one example of the coating applicator 40 for applying the buffer material 30. Of course, the coating applicator is not limited to the structure shown in FIG. 4 but may use any structure known in the art.

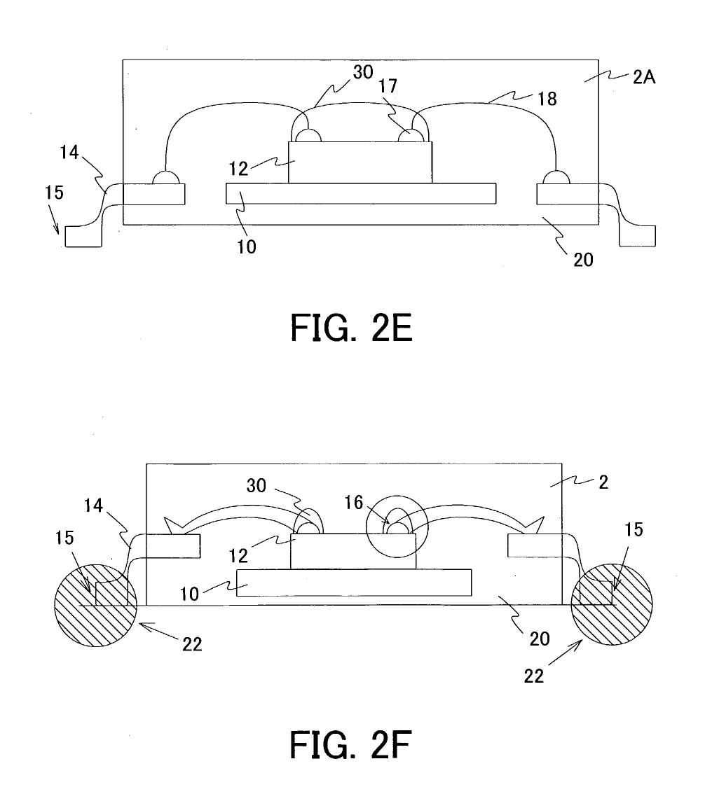

The instant embodiment applies the buffer material 30 onto each bonding pad part 16. FIG. 3 shows a schematic perspective view showing this state. Referring to FIG. 3, the nozzle 49 applies the buffer material 30 onto each bonding pad part 16 along a locus shown by a broken line P. FIG. 4 shows a moving part 50 of the nozzle 49. The application timing is provided for each bonding pad part 16 in the instant embodiment, and the buffer material 30 is not applied between the bonding pad parts 16. This application method may be implemented, for example, by providing FIG. 4 with a controller (not shown) for controlling drives of the cylinder 46 and the moving part 50, and a sensor (not shown) for detecting a relationship between the nozzle 49 and the bonding pad part 16. For instance, the controller moves the nozzle 49 along the locus P by moving the moving part 50. The controller applies the buffer material 30 onto the bonding pad part 16 through the nozzle 49 by controlling the driving of the cylinder 46 when the nozzle 49 is located at a position corresponding to the bonding pad part 16 based on the sensor detection result. On the other hand, the controller may stop application by controlling driving of the cylinder 46 when the nozzle 49 is located between bonding pad parts 16 based on the sensor detection result.

Alternatively, the continuous application may be provided along the locus P. In this case, the buffer material 30 is applied between the bonding pad parts 16 and the bank of the buffer material 30 is formed along the locus P.

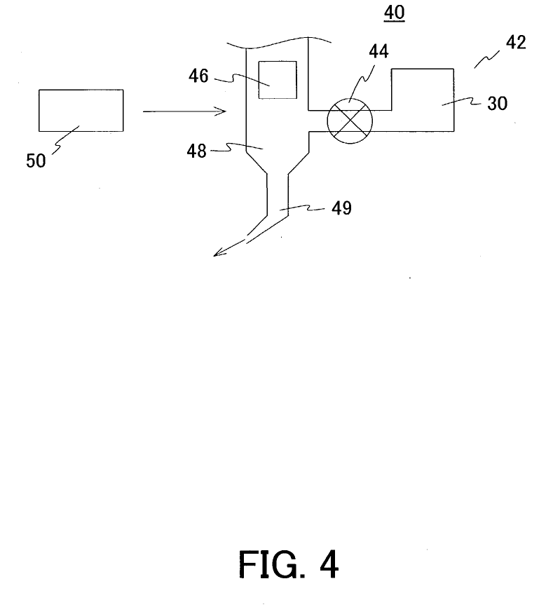

A description will be given of another embodiment of the present invention with reference to FIG. 5. Here, FIG. 5A is a schematic sectional view for explaining an application method of the other embodiment according to the present invention. FIG. 5B is a schematic plane view showing the IC chip 12 to which the buffer material 30 has been applied in accordance with this method. FIG. 5C is an XY sectional view in FIG. 5B.

The instant embodiment applies, through a nozzle 49a, the buffer material 30 onto the approximately entire surface of the IC chip 12 at its center. The nozzle 49a serves substantially as the nozzle 49, although its shape is different from the nozzle 49. Preferably, the instant embodiment uses low viscosity material for the buffer material 30 so that the buffer material 30 may cover the entire surface on the IC chip 12. As shown in FIG. 5A, when the buffer material 30 is applied to the center of the IC chip 12, the capillarity between wires 18 swells the buffer material 30 on the bonding pad part 16, as shown in FIG. 5C.

Then, as shown in FIG. 2D, the lead frame 14 connected to the IC chip 12 is attached to a molding die (not shown), and a molding die compound material (or plastic 20) is poured into the molding die at the temperature of 160° C. to 170° C. (step 1008). The molding die may be a multiple plunger molding die including a plurality of pairs of pot and plunger or a single plunger molding die including one pair of pot and plunger. As the temperature of the package 2 shown in FIG. 2D returns to the room temperature, the molding die compound hardens, completing the package 2 (step 1010). A package 2A shown in FIG. 2E would be used for the application method shown in FIG. 5.

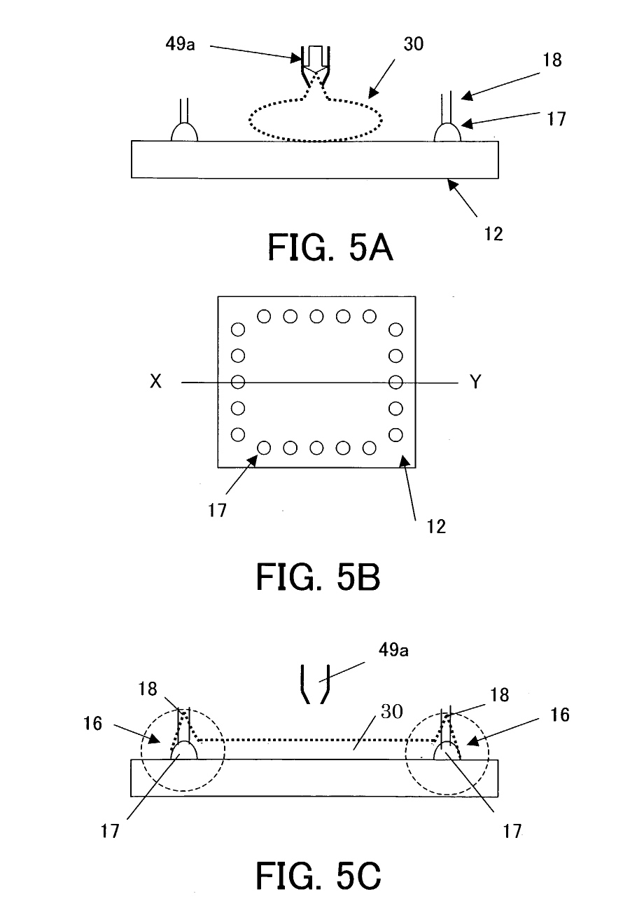

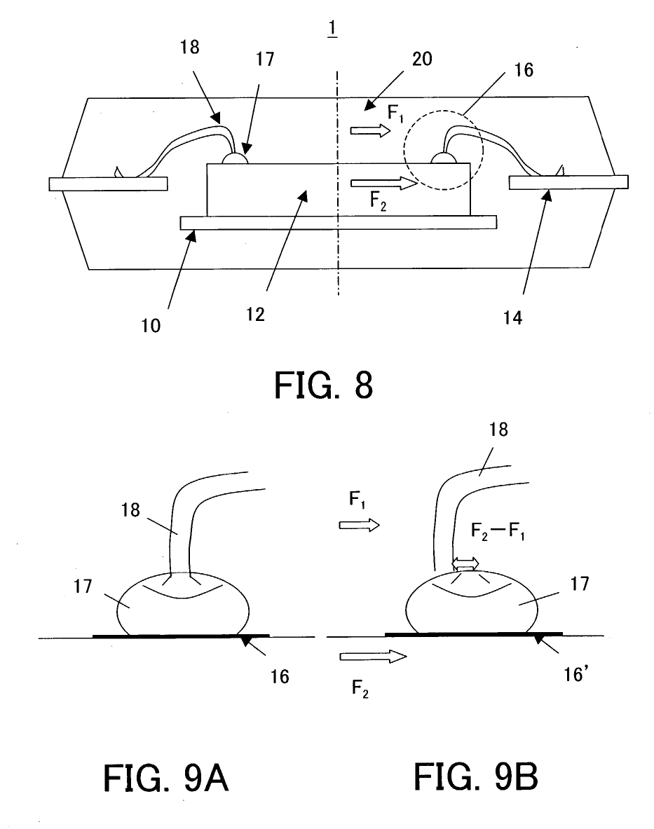

Next, as shown FIG. 2F, the package 2 (as well as the package 2A) are mounted on the printed board 24 using the unleaded solder 22 by soldering the terminal 15 of the lead frame 12. The unleaded solder 22 may use tin/silver alloy, tin/bismuth/silver alloy, tin/silver/cupper alloy, etc. These unleaded solders 22 have a melting point of about 260° C. higher than that of the widespread leaded solder. The inventive packages 2 and 2A do not cause any disconnection even under high temperature environments. A description will now be given of the bonding pad parts 16 under the high temperature environment with reference to FIG. 6. Here, FIG. 6 is a schematic sectional view of the bonding pad part 16 in the packages 2 and 2A in comparison with FIG. 9B.

As illustrated, the wire 18 is deformable between its interface 18a with the gold ball 17 and its interface 18b with the buffer material 30 is deformable like a linkage in the space h. More specifically, the buffer material 30 made of a jelly material in the package 2 may buffer the physical pressure caused by a difference of thermal stress F₂-F₁. The buffer material 3 made of a low-melting material in the package 2 may melt at high temperature during soldering, form the hollow space h, and buffer the physical pressure. This is true of the package 2A similar to the package 2 when the buffer material 30 is made of a jelly material or a low-melting material. As a result, the wire 18 and gold ball 17 are not easily disconnect from each other, as shown in FIG. 9B, the instant embodiment may provide a heat resistant packages 2 and 2A.

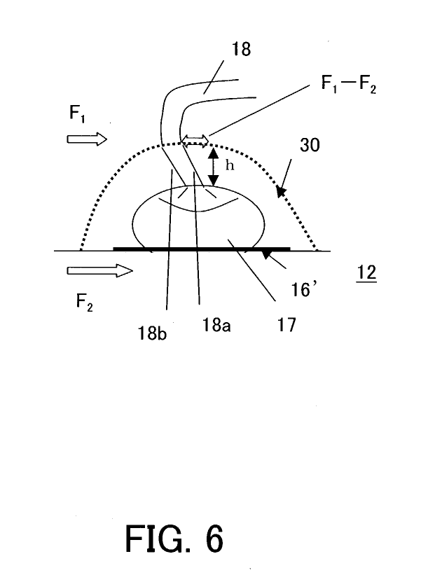

A printed circuit board onto which the package is mounted through unleaded solder 22 is applicable to various electronic apparatuses, such as computers, and its peripherals, cell phones, audio visual apparatuses, printers, etc. FIG. 7 shows a perspective overview of the laptop personal type computer 100 equipped with the printed circuit board 24.

The instant invention thus provides a semiconductor fabrication method and apparatus, which may manufacture a package having improved heat resistance, and a semiconductor device having the package.

Further, the present invention is not limited to these preferred embodiments, and various modifications and modifications may be made in the present invention without departing from the spirit and scope thereof.

What is claimed is:

1. A semiconductor fabrication method comprising the steps of:
bonding each of a plurality of bonding pads provided in a die and a circuit board using a wire;
coating an interface between the bonding pad and the wire with a buffer material; and
sealing the die and part of the circuit board using resin.

2. A semiconductor fabrication method according to claim 1, further comprising the step of using unleaded solder to mount, onto a printed board, a package that is formed by said sealing step and includes the resin, circuit board and die.

3. A semiconductor fabrication method according to claim 1, wherein the buffer material is made of a jelly material.

4. A semiconductor fabrication method according to claim 1, wherein the buffer material is made of a viscosity material.

5. A semiconductor fabrication method according to claim 1, wherein the buffer material has a melting point lower than temperature in said sealing step.

6. A semiconductor fabrication method according to claim 1, wherein said coating step applies the buffer material to each bonding pad.

7. A semiconductor fabrication method according to claim 1, wherein said coating step applies the buffer material such that the buffer material covers a row of the bonding pads.

8. A semiconductor fabrication method according to claim 1, wherein said coating step applies the buffer material from an approximately center on a surface of the die.

9. A semiconductor fabrication method according to claim 1, wherein the buffer material is silicon rubber.

10. A semiconductor device comprising:
a die having a plurality of bonding pads and bonded to a circuit board through the bonding pads and wires; and
a buffer material for coating an interface between the bonding pad in the die and the wire.

11. A semiconductor device comprising:
a package including a die that has a plurality of bonding pads and is bonded to a lead frame through the bonding pads and wires, and a buffer material for coating an interface between the bonding pad in the die and the wire; and
a printed board mounted with the package through unleaded soldering.

12. An electronic apparatus comprising a semiconductor device that includes a package including a die that has a plurality of bonding pads and is bonded to a lead frame through the bonding pads and wires, and a buffer material for coating an interface between the bonding pad in the die and the wire, and a printed board mounted with the package through unleaded soldering.

13. A semiconductor fabrication apparatus comprising:
an application part for applying a buffer material onto a die that has a plurality of bonding pads and is bonded to a circuit board through the bonding pads and wires, at an interface between the bonding pad and wire; and
a moving part for moving said application part such that said application part may apply the buffer material to the interface corresponding to each of the plurality of bonding pads.
